(19) United States
(12) Patent Application Publication
(10) Pub. No.: US 2026/0032952 A1
(43) Pub. Date: Jan. 29, 2026

(54) THIN FILM TRANSISTOR, AND DISPLAY APPARATUS COMPRISING THE SAME

(71) Applicant: LG Display Co., Ltd., Seoul (KR)

(72) Inventors: Sungju CHOI, Paju-si (KR); Jaeyoon PARK, Paju-si (KR); Hyeonjoo SEUL, Paju-si (KR); Dongyeon KANG, Paju-si (KR)

(73) Assignee: LG Display Co., Ltd., Seoul (KR)

(21) Appl. No.: 19/194,792

(22) Filed: Apr. 30, 2025

(30) Foreign Application Priority Data
Jul. 24, 2024 (KR) 10-2024-0098063

(51) Int. Cl. H10D 30/67; H10D 86/60

(52) U.S. Cl. CPC H10D 30/6704; H10D 30/6755; H10D 30/6757; H10D 86/60

(57) ABSTRACT

A thin film transistor includes an active layer; a depletion control layer on the active layer; and a gate electrode spaced apart from the active layer and overlapping at least partially with the active layer; wherein the active layer includes a channel portion overlapping at least partially with the gate electrode; a first connecting portion connected to one side of the channel portion; and a second connecting portion connected to the other side of the channel portion; wherein the depletion control layer overlaps at least a portion of the gate electrode in a plane, the depletion control layer includes a first material, the active layer includes a second material, the first material having a larger work function than the second material.

### CROSS-REFERENCE TO RELATED APPLICATIONS

This application claims the benefit of priority of the Korean Patent Application No. 10-2024-0098063 filed on Jul. 24, 2024, which is hereby incorporated by reference as if fully set forth herein.

### BACKGROUND

### Technical Field

The present disclosure relates to a thin film transistor and a display apparatus comprising the same.

### Discussion of the Related Art

Transistors are widely used as switching devices or driving devices in the field of electronic devices. In particular, since a thin film transistor may be manufactured on a glass substrate or a plastic substrate, it is widely used as a switching device of a display apparatus such as a liquid crystal display apparatus or an organic light emitting device.

Based on the material constituting the active layer, thin film transistors can be divided into amorphous silicon thin film transistors using amorphous silicon as the active layer, polycrystalline silicon thin film transistors using polycrystalline silicon as the active layer, and oxide semiconductor thin film transistors using oxide semiconductors as the active layer.

In an oxide semiconductor thin film transistor (TFT), since the oxide constituting the active layer can be formed at a relatively low temperature, has high mobility, and has a large resistance change according to the oxygen content, desired physical properties can be easily obtained. Also, due to the nature of the oxide, since the oxide semiconductor is transparent, it is also advantageous to implement a transparent display.

In oxide semiconductors, as the width of the active layer increases, the depth of conductorization penetration increases, which can reduce the length of the effective channel and degrade the device's drive stability. Therefore, techniques to control the depth of conductorization penetration are being continuously researched.

### SUMMARY

Accordingly, embodiments of the present disclosure are directed to a thin film transistor and a display apparatus comprising the same that substantially obviate one or more of the problems due to limitations and disadvantages of the related art.

An aspect of the present disclosure is to provide a thin film transistor in which the threshold voltage (Vth) is prevented or suppressed from being shifted in the negative direction by including a depletion control layer disposed on the active layer, even if the channel of the active layer has a short channel.

Another aspect of the present disclosure is to provide a thin film transistor in which the depth of conductorization penetration is controlled by including a depletion control layer disposed on the active layer, even if the channel of the active layer has a short channel.

Another aspect of the present disclosure is to provide a thin film transistor with improved reliability by including a depletion control layer disposed on the active layer.

Another aspect of the present disclosure is to provide a display device comprising such a thin film transistor.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a thin film transistor comprises an active layer; a depletion control layer on the active layer; and a gate electrode spaced apart from the active layer and overlapping at least partially with the active layer; wherein the active layer comprises a channel portion overlapping at least partially with the gate electrode; a first connecting portion connected to one side of the channel portion; and a second connecting portion connected to the other side of the channel portion; wherein the depletion control layer overlaps at least a portion of the gate electrode in a plane, the depletion control layer comprises a first material, the active layer comprises a second material, the first material having a larger work function than the second material.

The difference between the work function of the first material and the work function of the second material may be 0.3 eV or more.

The depletion control layer may be in contact with the active layer, forming a Schottky barrier with the active layer.

The active layer may comprise a depletion region overlapping the depletion control layer.

The region of the channel portion that overlaps with the depletion control layer may have a greater resistivity than the region that does not overlap with the depletion control layer.

The first material comprises a metal or an oxide semiconductor material, wherein the metal comprises at least one of gallium (Ga), zinc (Zn), tin (Sn), and titanium (Ti), and wherein the oxide semiconductor material is selected from the group consisting of IGZO (InGaZnO), GZO (GaZnO), IGO (InGaO), IZO (InZnO), GZTO (GaZnSnO), IGZTO (InGaZnSnO), ITO (InSnO), ITZO (InSnZnO)-based oxide semiconductor material, wherein the second material is IGZO (InGaZnO), GZO (GaZnO), IGO (InGaO), IZO (InZnO), GZTO (GaZnSnO), IGZTO (InGaZnSnO), ITO (InSnO), ITZO (InSnZnO)-based oxide semiconductor materials.

The depletion control layer may comprise a first depletion control layer overlapping at least a portion of the first connecting portion.

A region of the first connecting portion that overlaps the first depletion control layer may have a greater resistivity than a region that does not overlap the depletion control layer.

The first depletion control layer may include a first sub-depletion control layer and a second sub-depletion control layer, wherein the first sub-depletion control layer and the second sub-depletion control layer may be spaced apart from each other.

The depletion control layer may comprise a second depletion control layer overlapping at least a portion of the second connecting portion.

The region of the second connecting portion that overlaps with the second depletion control layer may have a greater resistivity than the region that does not overlap with the depletion control layer.

The second depletion control layer may include a first sub-depletion control layer and a second sub-depletion control layer, the first sub-depletion control layer and the second sub-depletion control layer being spaced apart from each other.

The depletion control layer includes a first depletion control layer overlapping at least a portion of the first connecting portion and a second depletion control layer overlapping at least a portion of the second connecting portion, wherein the first depletion control layer and the second depletion control layer may be spaced apart from each other.

The first depletion control layer and the second depletion control layer each comprise a first sub-depletion control layer and a second sub-depletion control layer, wherein the first sub-depletion control layer and the second sub-depletion control layer may be spaced apart from each other.

When a direction parallel to a straight line connecting the first connecting portion and the second connecting portion for the shortest distance is referred to as a first direction, any straight line parallel to the first direction and passing through a portion of the first depletion control layer may not pass through the second depletion control layer.

When the direction parallel to the straight line connecting the first connecting portion and the second connecting portion for the shortest distance is referred to as the first direction, any straight line parallel to the first direction and passing through a portion of the first depletion layer may pass through the second depletion layer.

The depletion control layer may comprise a third depletion control layer that does not overlap the first connecting portion and the second connecting portion.

The third depletion control layer may comprise a first sub-depletion control layer and a second sub-depletion control layer, the first sub-depletion control layer and the second sub-depletion control layer being spaced apart from each other.

Another embodiment of the present invention provides a display device comprising the thin film transistor.

It is to be understood that both the foregoing general description and the following detailed description are exemplary and explanatory and are intended to provide further explanation of the inventive concepts as claimed.

### BRIEF DESCRIPTION OF THE DRAWINGS

The disclosure and are incorporated in and constitute a part of this application, illustrate embodiments of the disclosure and together with the description serve to explain various principles. In the drawings:

FIG. 1 is a plan view of a thin film transistor according to one embodiment of the present invention.

FIG. 2 is a cross-sectional view cut along I-I′ of FIG. 1.

FIG. 3 is a cross-sectional view cut along II-II′ of FIG. 1.

FIG. 4 is a top view of a thin film transistor according to another embodiment of the present invention.

FIG. 5 is a top view of a thin film transistor according to another embodiment of the present invention.

FIG. 6 is a top view of a thin film transistor according to another embodiment of the present invention.

FIG. 7 is a top view of a thin film transistor according to another embodiment of the present invention.

FIG. 8 is a top view of a thin film transistor according to another embodiment of the present invention.

FIG. 9 is a top view of a thin film transistor according to another embodiment of the present invention.

FIG. 10 is a top view of a thin film transistor according to another embodiment of the present invention.

FIG. 11A is a top view of a thin film transistor according to a comparative example.

FIG. 11B is a top view of a thin film transistor according to an embodiment.

FIG. 12 is a graph illustrating current characteristics in a thin film transistor according to FIGS. 11A and 10B.

FIG. 13 is a schematic diagram of an indicator device according to one embodiment of the present invention.

FIG. 14 is a schematic diagram of one pixel of FIG. 13.

FIG. 15 is a top view of the pixel of FIG. 14.

FIG. 16 is a cross-sectional view cut along III-III′ of FIG. 15.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only-’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

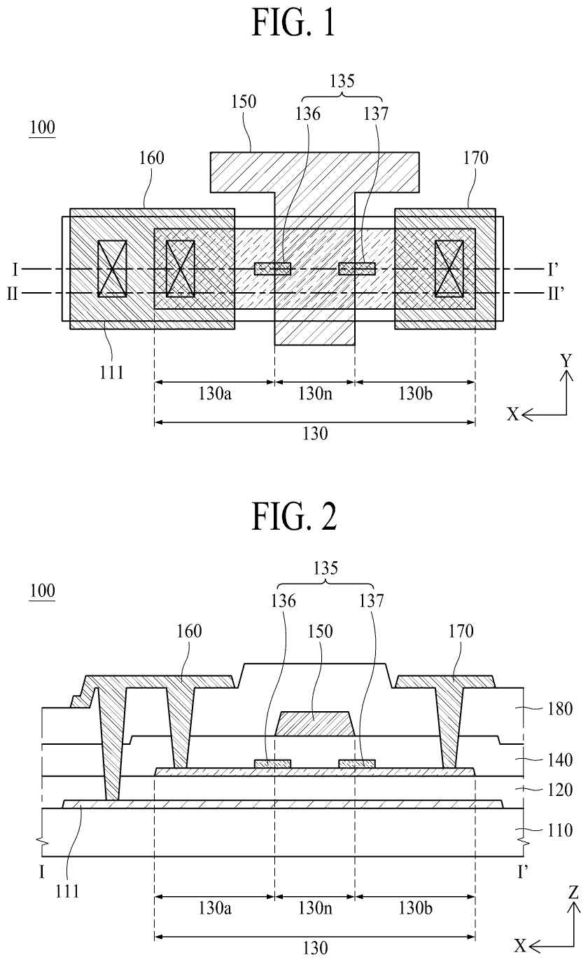

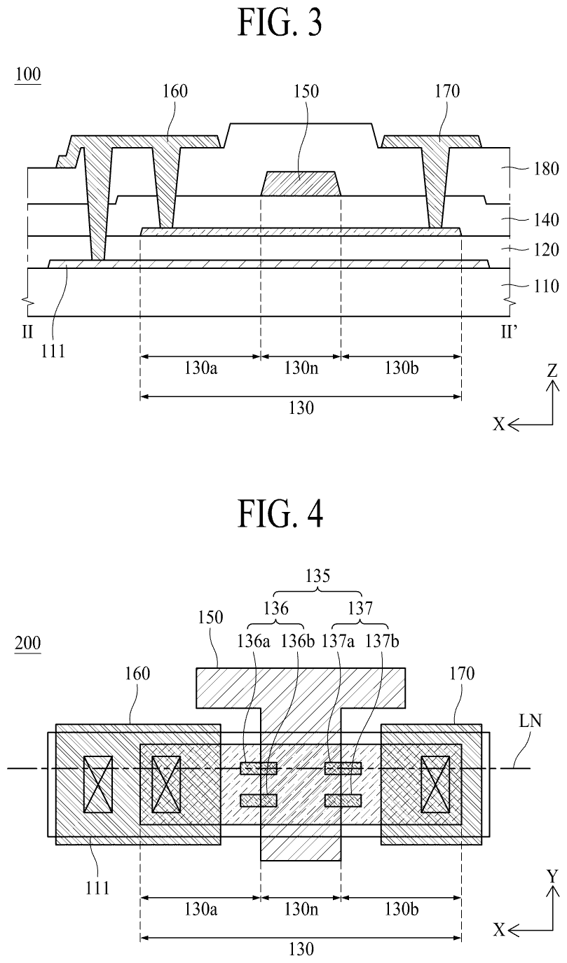

FIG. 1 is a top view of a thin film transistor 100 according to one embodiment of the present invention. FIG. 2 is a cross-sectional view cut along I-I′ of FIG. 1. FIG. 3 is a cross-sectional view cut along II-II′ of FIG. 1.

Referring to FIGS. 1, 2, and 3, a thin film transistor 100 according to one embodiment of the present disclosure may include an active layer 130, a depletion control layer 135, and a gate electrode 150.

Specifically, referring to FIGS. 1, 2, and 3, the thin film transistor 100 may include an active layer 130 on a base substrate 110, a depletion control layer 135 on the active layer 130, and a gate electrode 150 spaced apart from the active layer 130 and at least partially overlapping the active layer 130.

In accordance with one embodiment of the present invention, the thin film transistor 100 may further include a base substrate 110. Referring to FIGS. 2 and 3, the active layer 130 is disposed on the base substrate 110.

In accordance with one embodiment of the present invention, the thin film transistor 100 may further comprise a buffer layer 120. Referring to FIGS. 2 and 3, the active layer 130 is disposed on the buffer layer 120. Specifically, the buffer layer 120 is disposed between the base substrate 110 and the active layer 130.

In accordance with one embodiment of the present disclosure, the thin film transistor 100 may further include a gate insulating film 140. Referring to FIGS. 2 and 3, the gate insulating film 140 is disposed on the active layer 130. Specifically, the gate insulating film 140 is disposed between the active layer 130 and the gate electrode 150.

In accordance with one embodiment of the present disclosure, the thin film transistor 100 may further include an interlayer insulating film 180. Referring to FIGS. 2 and 3, the interlayer insulating film 180 is disposed on the gate electrode 150. Specifically, the gate electrode 150 is disposed between the gate insulating film 140 and the interlayer insulating film 180.

In accordance with one embodiment of the present disclosure, the thin film transistor 100 may further include a source electrode 160 and a drain electrode 170. Referring to FIGS. 1, 2, and 3, the source electrode 160 and the drain electrode 170 are disposed on an interlayer insulating film 180.

Hereinafter, the components of the thin film transistor 100 according to one embodiment of the present invention will be described in more detail.

The base substrate 110 may be made of glass or plastic. As a plastic, a transparent plastic having flexible properties, such as polyimide, may be utilized.

When polyimide is used as the base substrate 110, considering that the high temperature deposition process is performed on the base substrate 110, a heat-resistant polyimide that can withstand high temperatures may be used. In this case, for the formation of thin film transistors, processes such as deposition, etching, etc. may be performed while the polyimide substrate is disposed on a carrier substrate made of a highly durable material such as glass.

Referring to FIGS. 2 and 3, a buffer layer 120 may be disposed on the base substrate 110.

The buffer layer 120 is formed on the base substrate 110 and may be formed of an inorganic material or an organic material. For example, it may comprise an insulating oxide such as silicon oxide (SiOx), aluminum oxide (Al2O3), or the like.

The buffer layer 120 serves to protect the active layer 130 by blocking impurities such as moisture, oxygen, and the like from entering the base substrate 110, and to level the top of the base substrate 110, and may be formed as a single layer or multiple layers.

Referring to FIGS. 2 and 3, the active layer 130 may be disposed on the buffer layer 120.

The active layer 130 may include a channel portion 130n, a first connecting portion portion 130a, and a second connecting portion portion 130b.

Specifically, the active layer 130 may include a channel portion 130n that at least partially overlaps the gate electrode 150 in a plane, a first connecting portion 130a that does not overlap the gate electrode 150 in a plane and is connected to one side of the channel portion 130n, and a second connecting portion 130b that does not overlap the gate electrode 150 in a plane and is connected to the other side of the channel portion 130n.

According to one embodiment of the present invention, the first connecting portion 130a and the second connecting portion 130b are spaced apart from each other with the channel portion 130n interposed therebetween.

According to one embodiment of the present invention, the active layer 130 may be formed by a semiconductor material. The active layer 130 may comprise an oxide semiconductor material.

The oxide semiconductor material may be, for example, an InZnO (IZO)-based oxide semiconductor material, an InGaO (IGO)-based oxide semiconductor material, an ITO (InSnO)-based oxide semiconductor material, an IGZO (InGaZnO)-based oxide semiconductor material, an IGZTO (InGaZnSnO)-based oxide semiconductor material, GZTO (GaZnSnO)-based oxide semiconductor material, GZO (GaZnO)-based oxide semiconductor material, ITZO (InSnZnO)-based oxide semiconductor material, and FIZO (FeInZnO)-based oxide semiconductor material. However, one embodiment of the present invention is not limited thereto, and the active layer 130 may be made of other oxide semiconductor materials known in the art.

The first connecting portion 130a and the second connecting portion 130b may be formed by selective conductorization of the active layer 130 made of a semiconductor material. According to one embodiment of the present invention, imparting conductivity to certain regions of the active layer 130 so that it can act as a conductor is referred to as selective conductorization.

For example, the active layer 130 may be selectively conductorized by ion doping. As a result, the first connecting portion 130a and the second connecting portion 130b may be formed. However, one embodiment of the present invention is not limited to this, and the active layer 130 may be selectively conductorized by other methods known in the art.

The first connecting portion 130a and second connecting portion 130b do not overlap with the gate electrode 150. The first connecting portion 130a and the second connecting portion 130b have good electrical conductivity and high mobility compared to the channel portion 130n. Therefore, the first connecting portion 130a and the second connecting portion 130b can serve as wiring, respectively.

According to one embodiment of the present invention, the thin film transistor 100 may include a depletion control layer 135 on the active layer 130.

Specifically, referring to FIGS. 1, 2, and 3, the depletion control layer 135 can overlap at least a portion of the gate electrode 150 in a plane.

Referring to FIGS. 1, 2, and 3, the active layer 130 can be disposed between the base substrate 110 and the depletion control layer 135, respectively.

More specifically, the depletion control layer 135 is disposed on the active layer 130, in contact with the active layer 130.

In this case, the depletion control layer 135 and the active layer 130 include a first material and a second material, respectively. The first material may have a larger work function than the second material.

The first material may include a metal or an oxide semiconductor material.

For example, the metal may include at least one of gallium (Ga), zinc (Zn), tin (Sn), and titanium (Ti). However, embodiments of the present invention are not limited to these, and may include any material having a large work function relative to the second material.

The oxide semiconductor material comprising the first material may include at least one of IGZO (InGaZnO), GZO (GaZnO), IGO (InGaO), IZO (InZnO), GZTO (GaZnSnO), IGZTO (InGaZnSnO), ITO (InSnO), ITZO (InSnZnO)-based oxide semiconductor material. However, embodiments of the present invention are not limited to these, and may include any material having a large work function compared to the second material.

The second material may comprise an oxide semiconductor material. For example, the oxide semiconductor material comprised by the second material may include at least one of IZO (InZnO), IGO (InGaO), ITO (InSnO), IGZO (InGaZnO), IGZTO (InGaZnSnO), GZTO (GaZnSnO), GZO (GaZnO), ITZO (InSnZnO), and FIZO (FeInZnO)-based. However, embodiments of the present invention are not limited to these, and may include materials having a smaller work function compared to the first material.

By contacting the depletion control layer 135 comprising the first material with a large work function and the active layer 130 comprising the second material with a small work function, electrons contained in the active layer 130 may migrate to the depletion control layer 135 and form a Schottky barrier in the active layer 130. A Schottky barrier is a barrier of electrical potential that occurs when a metal and a semiconductor come into contact. The Schottky barrier controls the flow of current.

By contacting the depletion control layer 135 with the active layer 130, a Schottky barrier is formed, which may result in the formation of a depletion region in the active layer 130. According to one embodiment of the present invention, the active layer 130 has a depletion region formed in a region overlapping the depletion control layer 135.

According to one embodiment of the present invention, the depletion region is formed in the channel portion 130n of the active layer 130, and current cannot flow through the depletion region. Specifically, a region of the channel portion 130n that overlaps with the depletion control layer 135 may have a greater resistivity than a region that does not overlap with the depletion control layer 135.

Furthermore, in the plane, the resistivity may decrease as one moves away from the region of overlap between the active layer 130 and the depletion control layer 135 by 0.1 μm.

According to one embodiment of the present invention, when a direction parallel to the shortest line connecting the first connecting portion portion 130a and the second connecting portion portion 130b is referred to as the first direction X, a length of the channel portion 130n along the first direction X may be defined as a length of the channel portion, and when a direction perpendicular to the first direction X is referred to as the second direction Y, a width of the channel portion 130n along the second direction Y may be defined as a width of the channel portion.

If the channel portion 130n has a large width, when conducting for the first connecting portion 130a and the second connecting portion 130b, the boundary surface between the channel portion 130n and the conducting portion increases, and the conductorization diffusion towards the channel portion 130n may be greatly advanced. If the conductorization diffusion toward the channel portion 130n is greatly advanced, the threshold voltage (Vth) of the thin film transistor 100 may move in the negative (−) direction, which may cause the driving stability of the thin film transistor 100 to deteriorate.

On the other hand, if the channel portion 130n has a small width, when conducting for the first connecting portion 130a and the second connecting portion 130b, the boundary between the channel portion 130n and the conducting portion may be narrowed so that the conductorization diffusion toward the channel portion 130n may be suppressed.

According to one embodiment of the present invention, when the depletion control layer 135 is disposed on the active layer 130, a depletion region is formed in a region of the active layer 130 that overlaps with the depletion control layer 135. As a result, the area where the conductivization can spread is narrowed at the boundary surface between the channel portion 130n and the first connecting portion 130a and the boundary surface between the channel portion 130n and the second connecting portion 130b, and the conductorization diffusion toward the channel portion 130n can be suppressed.

According to one embodiment of the present invention, the first material may have a larger work function than the second material. Preferably, the difference between the work function of the first material and the work function of the second material may be 0.3 eV or more.

When the difference between the work function of the first material and the work function of the second material is greater than 0.3 eV, a depletion region may be well formed in the region overlapping the depletion control layer 135 of the active layer 130. As a result, conductorization diffusion may be prevented at the boundary between the channel portion 130n and the first connecting portion 130a and the boundary between the channel portion 130n and the second connecting portion 130b.

However, if the difference between the work function of the first material and the work function of the second material is less than 0.3 eV, or if the work function of the first material is smaller than the work function of the second material, difficulties may arise in forming a depletion region in a region of the active layer 130 that overlaps with the depletion control layer 135. As a result, conductorization diffusion may occur at the boundary between the channel portion 130n and the first connecting portion 130a and at the boundary between the channel portion 130n and the second connecting portion 130b.

According to one embodiment of the present invention, the depletion control layer 135 may have a length of 0.5 μm or more with respect to the first direction (X). Furthermore, it may have a length of 0.5 μm or more relative to the second direction (Y).

Referring to FIG. 1, the depletion control layer 135 may have a length of 0.5 μm or more in the first direction (X) and the second direction (Y). In this case, the length refers to a maximum length of the depletion control layer 135 in the first direction (X) or the second direction (Y).

In FIG. 1, the depletion control layer 135 is shown to be square in a plane. However, one embodiment of the present invention is not limited to this, and may be polygonal, circular, bow-shaped, or the like.

According to one embodiment of the present invention, the depletion control layer 135 can include a first depletion control layer 136 that overlaps at least a portion of the first connecting portion 130a.

Specifically, the first depletion control layer 136 overlaps the gate electrode 150 and also overlaps the first connecting portion 130a.

FIG. 1 illustrates a planar view of the first depletion control layer 136 overlapping the gate electrode 150 and overlapping the first connecting portion 130a.

According to one embodiment of the present invention, regions of the first connecting portion 130a that overlap with the first depletion control layer 136 in a plane view may have a greater resistivity than regions that do not overlap with the first depletion control layer 136. Specifically, the resistivity may decrease as one moves away from the boundary portion of the first connecting portion 130a and the first depletion control layer 136 in the plane. More specifically, the resistivity may decrease with distance from the boundary portion of the first connecting portion 130a and the first depletion control layer 136 within the first connecting portion 130a to a range of up to 0.1 μm in a plane.

According to one embodiment of the present invention, the depletion control layer 135 may include a second depletion control layer 137 that overlaps at least a portion of the second connecting portion 130b.

Specifically, the second depletion control layer 137 overlaps the gate electrode 150 and also overlaps the second connecting portion 130b.

FIG. 1 illustrates a planar view of the second depletion control layer 137 overlapping the gate electrode 150 and overlapping the second connecting portion 130b.

According to one embodiment of the present invention, regions of the second connecting portion 130b that overlap with the second depletion control layer 137 in a plane view may have a greater resistivity than regions that do not overlap with the second depletion control layer 137. Specifically, the resistivity may decrease as one moves away from the boundary portion of the second connecting portion 130b and the second depletion control layer 137 in the plane. More specifically, the resistivity may decrease with distance from the boundary portion of the second connecting portion 130b and the second depletion control layer 137 within the second connecting portion 130b to a range of up to 0.1 μm in a plane.

According to one embodiment of the present invention, the depletion control layer 135 may comprise both the first depletion control layer 136 and the second depletion control layer 137. FIG. 1 illustrates a depletion control layer 135 comprising both a first depletion control layer 136 and a second depletion control layer 137.

Specifically, the first depletion control layer 136 and the second depletion control layer 137 are disposed spaced apart from each other with at least a portion of the channel portion 130n interposed therebetween.

More specifically, in a plane view, the first depletion control layer 136 and second depletion control layer 137 spaced apart from each other have a protruding appearance from the gate electrode 150.

While FIG. 1 illustrates the depletion control layer 135 having a singular first depletion control layer 136 and a singular second depletion control layer 137, one embodiment of the present invention is not limited thereto, and the first depletion control layer 136 and the second depletion control layer 137 may each include a plurality of sub-depletion control layers.

According to one embodiment of the present invention, the first depletion control layer 136 may include a first sub-depletion control layer 136a and a second sub-depletion control layer 136b. The first sub-depletion control layer 136a and the second sub-depletion control layer 136b are spaced apart from each other.

FIG. 4 illustrates a first depletion control layer 136 including a first sub-depletion control layer 136a and a second sub-depletion control layer 136b spaced apart from each other. A portion of the first sub-depletion control layer 136a may overlap with the gate electrode 150, and another portion of the first sub-depletion control layer 136a may overlap with the first connecting portion 130a. Further, a portion of the second sub-depletion control layer 136b may overlap the gate electrode 150, and another portion of the second sub-depletion control layer 136b may overlap the first connecting portion 130a.

The order of placement of the first sub-depletion control layer 136a and the second sub-depletion control layer 136b is not limited to that shown in FIG. 4. Also, although not shown, the first depletion control layer 136 may include a third sub-depletion control layer or a fourth sub-depletion control layer.

According to one embodiment of the present invention, the second depletion control layer 137 may include a first sub-depletion control layer 137a and a second sub-depletion control layer 137b. The first sub-depletion control layer 137a and the second sub-depletion control layer 137b are spaced apart from each other.

FIG. 4 illustrates a second depletion control layer 137 comprising a first sub-depletion control layer 137a and a second sub-depletion control layer 137b spaced apart from each other. A portion of the first sub-depletion control layer 137a may overlap with the gate electrode 150, and another portion of the first sub-depletion control layer 137a may overlap with the second connecting portion 130b. Further, a portion of the second sub-depletion control layer 137b may overlap with the gate electrode 150, and another portion of the second sub-depletion control layer 137b may overlap with the second connecting portion 130b.

The order of arrangement of the first sub-depletion control layer 137a and the second sub-depletion control layer 137b is not limited to that shown in FIG. 4. Also, although not shown, the second depletion control layer 137 may include a third sub-depletion control layer or a fourth sub-depletion control layer.

FIG. 4 illustrates the first depletion control layer 136 and the second depletion control layer 137 comprising first sub-depletion control layers 136a, 137a and second sub-depletion control layers 136b, 137b, respectively. Specifically, the first sub-depletion control layer 136a, 137a and the second sub-depletion control layer 136b, 137b are spaced apart from each other.

Referring to FIG. 4, any straight line LN parallel to the first direction X and passing through a portion of the first depletion control layer 136 may pass through the second depletion control layer 137.

Specifically, the first depletion control layer 136 and the second depletion control layer 137 may be overlapped with each other in the first direction (X).

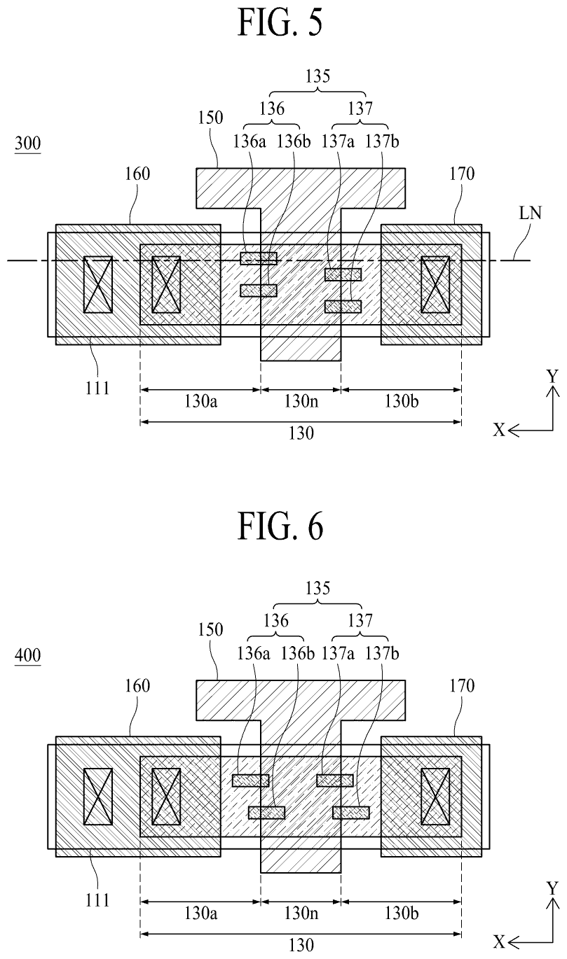

However, one embodiment of the present invention is not limited to this, and any straight line LN parallel to the first direction X and passing through a portion of the first depletion control layer 136 may not pass through the second depletion control layer 137 (see FIG. 5).

Specifically, referring to FIG. 5, the first depletion control layer 136 and the second depletion control layer 137 may not overlap each other in the first direction X.

Referring to FIG. 6, the first depletion control layer 136 and the second depletion control layer 137 of the depletion control layer 135 may include first sub-depletion control layers 136a, 137a and second sub-depletion control layers 136b, 137b, respectively. in a plane, the size of the region where the first sub-depletion control layer 136a of the first depletion control layer 136 overlaps the gate electrode 150 may be different from the size of the region where the second sub-depletion control layer 136b overlaps the gate electrode 150. Further, the size of the region where the first sub-depletion control layer 137a of the second depletion control layer 137 overlaps the gate electrode 150 in a plane can be different from the size of the region where the second sub-depletion control layer 137b overlaps the gate electrode 150.

FIG. 6 illustrates, in a plane view, the second sub-depletion control layer 136b of the first depletion control layer 136 being disposed closer to the center of the gate electrode 150 as compared to the first sub-depletion control layer 136a, and in a plane view, the first sub-depletion control layer 137a of the second depletion control layer 137 being disposed closer to the center of the gate electrode 150 as compared to the second sub-depletion control layer 137b. However, one embodiment of the present invention is not limited to this, and the positions of the first sub-depletion control layer 136a and the second sub-depletion control layer 136b may be reversed, and the positions of the first sub-depletion control layer 137a and the second sub-depletion control layer 137b may be reversed.

For example, either of the first sub-depletion control layer 136a and the second sub-depletion control layer 136b of the first depletion control layer 136 may be disposed closer to a center of the gate electrode 150 in a plane than the other, and may be disposed closer to a center of the channel portion 130n. For example, one of the first sub-depletion control layer 136a and the second sub-depletion control layer 136b of the first depletion control layer 136 may have a longer length of a region overlapping the gate electrode 150 relative to the first direction X in a plane than the other.

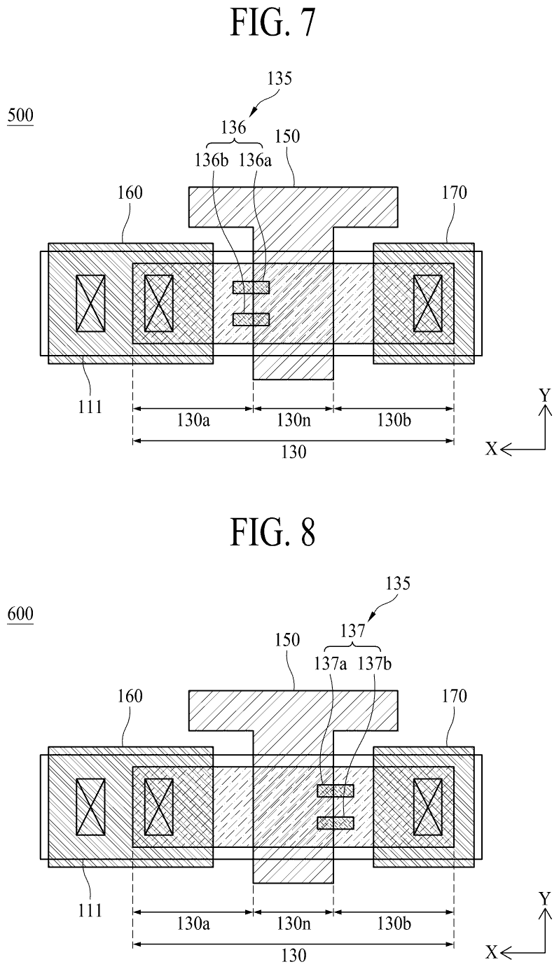

Referring to FIG. 7, the depletion control layer 135 may include only the first depletion control layer 136. Specifically, the depletion control layer 135 may be disposed spaced apart from the second connecting portion 130b while overlapping the gate electrode 150.

However, one embodiment of the present invention is not limited to this, and the depletion control layer 135 may include only the second depletion control layer 137. Specifically, referring to FIG. 8, the depletion control layer 135 may be disposed spaced apart from the first connecting portion 130a while overlapping the gate electrode 150.

According to one embodiment of the present invention, the depletion control layer 135 may include a third depletion control layer 138 that does not overlap the first connecting portion 130a and the second connecting portion 130b.

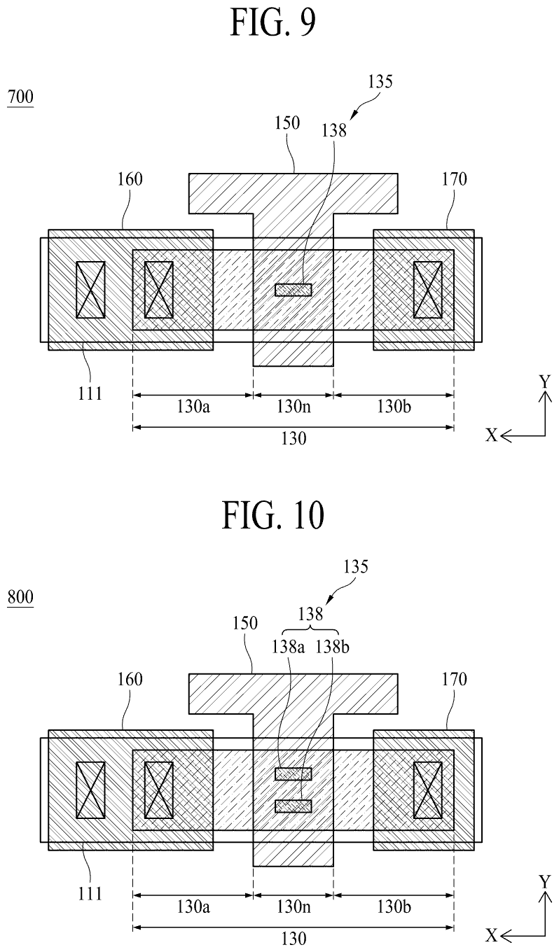

Referring to FIG. 9, in a plane view, the entirety of the third depletion control layer 138 may overlap with the gate electrode 150. While FIG. 9 illustrates the third depletion control layer 138 disposed centrally over the gate electrode 150 in a plane, one embodiment of the present invention is not limited thereto, and the third depletion control layer 138 may be disposed proximate to either the first connecting portion 130a or the second connecting portion 130b. Additionally, the third depletion control layer 138 may be disposed at a boundary of the gate electrode 150 in a plane.

When the depletion control layer 135 includes the third depletion control layer 138, a depletion region is formed in a region of the channel portion 130n that overlaps with the third depletion control layer 138 in a plane. As a result, the conductorization diffusion into the channel portion 130n may be inhibited.

According to one embodiment of the present invention, the third depletion control layer 138 may include a first sub-depletion control layer 138a and a second sub-depletion control layer 138b.

FIG. 10 illustrates the first sub-depletion control layer 138a and the second sub-depletion control layer 138b spaced apart from each other in a plane view and arranged in overlap with the gate electrode 150. According to one embodiment of the present invention, the order of placement of the first sub-depletion control layer 138a and second sub-depletion control layer 138b of the third depletion control layer 138 may be reversed. Also, although not shown in the figures, the third depletion control layer 138 may include a third sub-depletion control layer and a fourth sub-depletion control layer.

According to one embodiment of the present invention, the active layer 130 may have a multi-layer structure. For example, although not shown in the drawings, the active layer 130 may include a first active layer and a second active layer.

The first active layer and the second active layer may comprise the same semiconductor material, or may comprise different semiconductor materials.

According to one embodiment of the present invention, the thin film transistor 100 may further include a gate insulating film 140 between the active layer 130 and the gate electrode 150. Specifically, the gate insulating film 140 may cover the entire top surface of the active layer 130. FIG. 2 illustrates a configuration in which the gate insulating film 140 covers the entire top surface of the active layer 130.

However, one embodiment of the present invention is not limited to this, and the first connecting portion 130a and second connecting portion 130b of the active layer 130 may be exposed from the gate insulating film 140.

The gate insulating film 140 may comprise at least one of a silicon oxide, a silicon nitride, and a metal-based oxide. The gate insulating film 140 may have a monolayer structure, or may have a multilayer structure. The gate insulating film 140 protects the channel portion 130n.

Referring to FIG. 2, a gate electrode 150 is disposed on the gate insulating film 140. The gate electrode 150 overlaps the channel portion 130n of the active layer 130.

The gate electrode 150 may comprise at least one of an aluminium-based metal, such as aluminium (Al) or an aluminium alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). The gate electrode 150 may also have a multilayer film structure comprising at least two conductive films having different physical properties.

Referring to FIG. 2, an interlayer insulating film 180 is disposed on the gate electrode 150 and the gate insulating film 140. The interlayer insulation film 180 is an insulating layer made of an insulating material. The interlayer insulating film 180 may be made of an organic material, an inorganic material, or a laminate of an organic layer and an inorganic layer.

Referring to FIG. 2, a source electrode 160 and a drain electrode 170 are disposed on the interlayer insulating film 180.

Although not shown, the source electrode 160 and the drain electrode 170 are disposed on the gate insulating film 140 and may be disposed on the same layer as the gate electrode 150. The source electrode 160 and drain electrode 170 may be made by the same process from the same material as the gate electrode 150.

Each of the source electrode 160 and the drain electrode 170 may comprise at least one of the following metals: an aluminium-based metal such as aluminium (Al) or an aluminium alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The source electrode 160 and the drain electrode 170 may each have a multilayer film structure comprising at least two conductive films having different physical properties.

Referring to FIGS. 1 and 2, the source electrode 160 and the drain electrode 170 are each connected to the active layer 130 via contact holes. Specifically, the source electrode 160 and the drain electrode 170 are connected to the active layer 130 by contacting the first connecting portion 130a and the second connecting portion 130b, respectively.

Referring to FIGS. 1, 2, and 3, a light shielding layer 111 may be disposed on the base substrate 110. Specifically, the light shielding layer 111 may be disposed between the base substrate 110 and the active layer 130. The light-shielding layer 111 overlaps the channel portion 130n. The light-shielding layer 111 protects the channel portion 130n by blocking light incident from the outside.

The light-shielding layer 111 may be made of a material having light-blocking properties. The light shielding layer 111 may comprise at least one of an aluminium-based metal, such as aluminium (Al) or an aluminium alloy, a molybdenum-based metal, such as molybdenum (Mo) or a molybdenum alloy, chromium (Cr), tantalum (Ta), neodymium (Nd), titanium (Ti) and iron (Fe). According to one embodiment of the present invention, the light shielding layer 111 may be electrically conductive.

The light shielding layer 111 may be omitted. Although not shown in FIGS. 1, 2, and 3, a buffer layer may additionally be disposed between the base substrate 110 and the light shielding layer 111. The light shielding layer 111 may be electrically connected to any one of the source electrode 160 and the drain electrode 170. FIG. 2 illustrates a configuration in which the light shielding layer 111 is electrically connected to the source electrode 160.

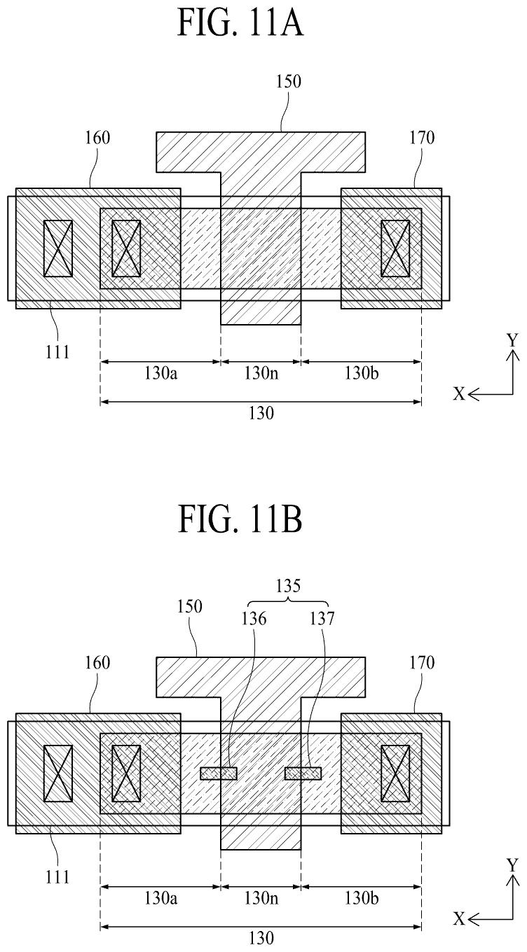

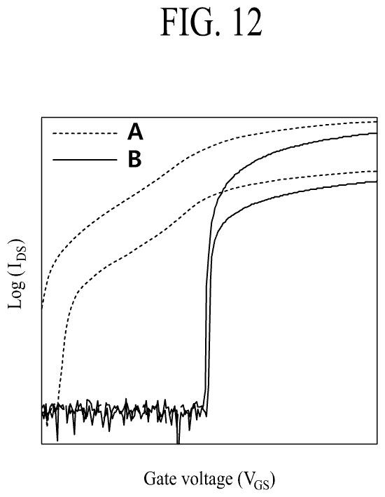

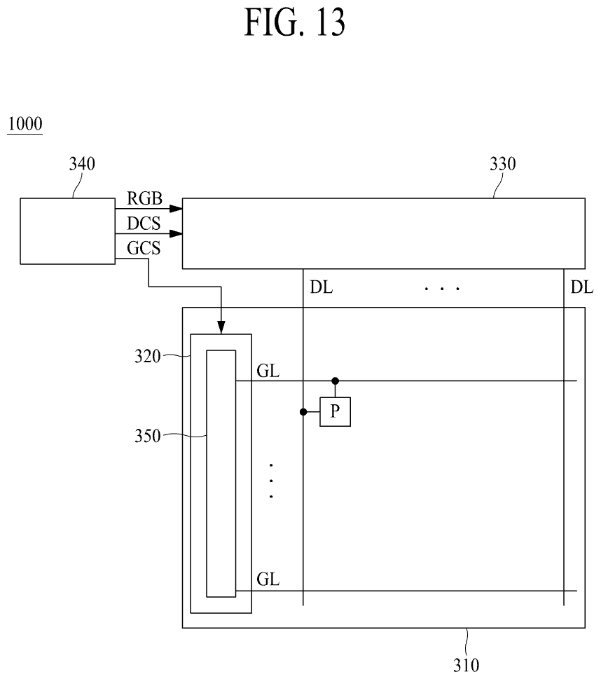

FIGS. 11A and 11B are top views of thin-film transistors according to comparative examples and embodiments, and FIG. 12 is a graph illustrating current characteristics in the thin-film transistors according to FIGS. 11A and 11B.

In the graph of FIG. 12, the horizontal axis refers to the gate voltage (VG), and the vertical axis refers to the logarithmic value of the drain-source current (IDS). Further, A in FIG. 12 illustrates a current characteristic of a thin film transistor according to FIGS. 11a, and B in FIG. 12 illustrates a current characteristic of a thin film transistor according to FIG. 11b.

FIG. 11a is a top view of a thin film transistor according to a comparative example, in which a depletion control layer 135 is not disposed on the active layer 130. On the other hand, FIG. 11b is a top view of a thin film transistor according to an embodiment, wherein the depletion control layer 135 is disposed on the active layer 130. Specifically, a first depletion control layer 136 and a second depletion control layer 137 are shown in FIG. 11B, but one embodiment of the present invention is not limited thereto, and a third depletion control layer 138 may be disposed on the active layer 130.

In an embodiment where a depletion control layer 135 is disposed on the active layer 130 (see FIG. 11b), a region of the active layer 130 that overlaps with the depletion control layer 135 may form a Schottky barrier upon contact with the depletion control layer 135, and a depletion region may be formed in the active layer 130. As a result, even when the active layer 130 has a large channel width, the area in which conductorization can diffuse at the interface between the channel portion 130n and the first connecting portion 130a and the interface between the channel portion 130n and the second connecting portion 130b may be narrowed, thereby inhibiting the conductorization diffusion towards the channel portion 130n.

Thus, when the conductorization into the channel portion 130n is suppressed or controlled, the length of the depth of conductorization penetration is shortened, resulting in a relatively large effective channel length. Furthermore, when the conductorization into the channel portion 130n is suppressed or controlled, the movement of the threshold voltage (Vth) of the thin film transistor in the negative (−) direction is controlled, and the driving stability of the thin film transistor can be improved.

On the other hand, in a comparative example (see FIG. 11A) in which the depletion control layer 135 is not disposed on the active layer 130, conductorization may occur at the boundary of the channel portion 130n and the first connecting portion 130a and at the boundary of the channel portion 130n and the second connecting portion 130b due to the depletion control layer 135 not being disposed on the active layer 130.

Therefore, when conductorization into the channel portion 130n is carried out, the length of the depth of conductorization penetration is lengthened, resulting in a relatively short effective channel length. Furthermore, if conductorization to the channel portion 130n is performed, the threshold voltage (Vth) of the thin film transistor may be shifted to the negative (−) direction, thereby reducing the drive stability of the thin film transistor.

FIG. 13 is a schematic diagram illustrating a display apparatus 1000 according to further still another embodiment of the present disclosure.

As shown in FIG. 13, the display apparatus 1000 according to further still another embodiment of the present disclosure may include a display panel 310, a gate driver 320, a data driver 330 and a controller 340.

The display panel 310 includes gate lines GL and data lines DL, and pixels P are disposed in intersection areas of the gate lines GL and the data lines DL. An image is displayed by driving of the pixels P. The gate lines GL, the data lines DL and the pixels P may be disposed on the base substrate 110.

The controller 340 controls the gate driver 320 and the data driver 330.

The controller 340 outputs a gate control signal GCS for controlling the gate driver 320 and a data control signal DCS for controlling the data driver 330 by using a signal supplied from an external system not shown. Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 into an analog data voltage and supplies the data voltage to the data lines DL.

According to one embodiment of the present disclosure, the gate driver 320 may be packaged on the display panel 310. In this way, a structure in which the gate driver 320 is directly packaged on the display panel 310 will be referred to as a Gate In Panel (GIP) structure. In detail, in the Gate In Panel (GIP) structure, the gate driver 320 may be disposed on the base substrate 110.

The display apparatus 1000 according to one embodiment of the present disclosure may include the above-described thin film transistors 100, 200, 300, 400, 500, 600, 700, and 800. According to one embodiment of the present disclosure, the gate driver 320 may include the above-described thin film transistors 100, 200, 300, 400, 500, 600, 700, and 800.

The gate driver 320 may include a shift register 350.

The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

The shift register 350 may include the above-described thin film transistors 100, 200, 300, 400, 500, 600, 700, and 800.

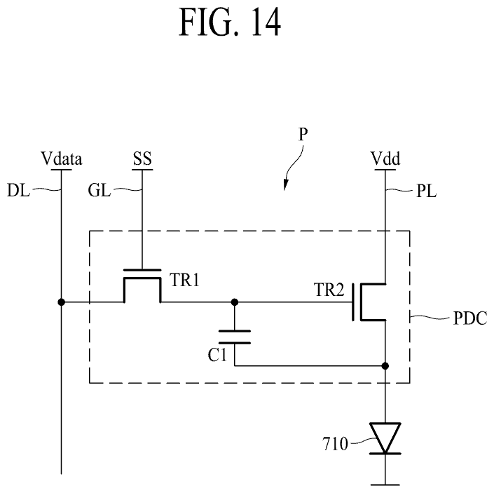

FIG. 14 is a circuit view illustrating any one pixel P of FIG. 13.

The circuit view of FIG. 14 is an equivalent circuit view for the pixel P of the display apparatus 1000 that includes an organic light emitting diode (OLED) as a display element 710.

Referring to FIG. 14, the pixel P includes a display element 710 and a pixel driving circuit PDC for driving the display element 710. In detail, the display apparatus 1000 according to one embodiment of the present disclosure may include a pixel driving circuit PDC on the base substrate 110.

The pixel driving circuit PDC of FIG. 14 includes a first thin film transistor TR1 that is a switching transistor and a second thin film transistor TR2 that is a driving transistor. The display apparatus 1000 according to another embodiment of the present disclosure may include at least one of the above-described thin film transistors 100, 200, 300, 400, 500, 600, 700, and 800.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor C1 formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 may be controlled.

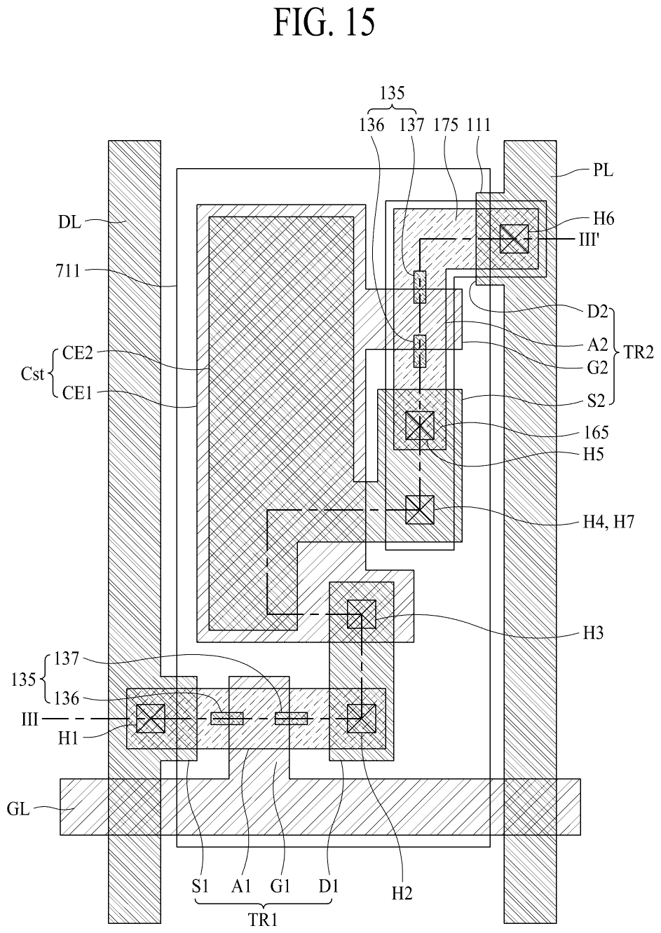

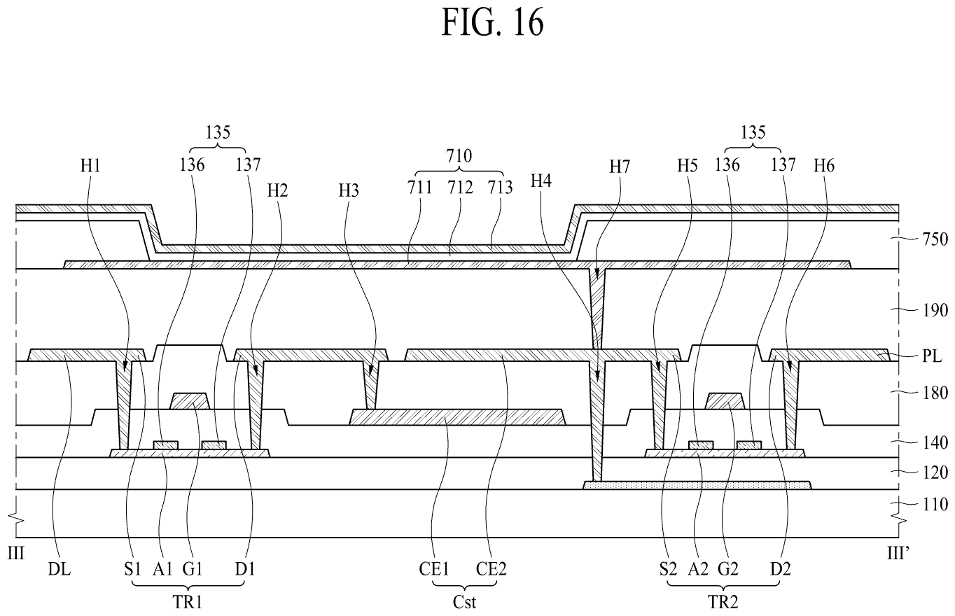

FIG. 15 is a plan view of the pixel of FIG. 14, and FIG. 16 is a cross-sectional view cut along III-III′ of FIG. 14.

Referring to FIGS. 15 and 16, a first thin film transistor TR1 and a second thin film transistor TR2 are disposed on a base substrate 110.

The base substrate 110 may be made of glass or plastic. As the base substrate 110, a plastic having flexible properties, such as polyimide (PI), may be used.

A light shielding layer 111 is disposed on the base substrate 110. The light-shielding layer 111 may have light-blocking properties. The light-shielding layer 111 may protect the active layers A1, A2 by blocking light incident from the outside.

A buffer layer 120 is disposed on the light-shielding layer 111. The buffer layer 120 is made of an insulating material and protects the active layers A1, A2 from moisture, oxygen, and the like entering from the outside.

The active layer A1 of the first thin film transistor TR1 and the active layer A2 of the second thin film transistor TR2 are disposed on the buffer layer 120.

The active layers A1, A2 may comprise, for example, an oxide semiconductor material. The active layers A1, A2 may have a multilayer structure of oxide semiconductor material.

A depletion control layer 135 may be disposed on the active layers A1, A2.

According to one embodiment of the present invention, the depletion control layer 135 may comprise a first depletion control layer 136 and a second depletion control layer 137.

The depletion layer 135 may comprise a first material and the active layer 130 may comprise a second material. Specifically, the first material may have a larger work function than the second material.

A gate insulating film 140 is disposed on the active layers A1, A2. The gate insulating film 140 covers the top surface of the active layers A1, A2.

On the gate insulating film 140, the gate electrode G1 of the first thin-film transistor TR1 and the gate electrode G2 of the second thin-film transistor TR2 are disposed.

Although not shown, a gate line GL may be disposed on the gate insulating film 140. The gate electrode G1 of the first thin film transistor TR1 may extend from the gate line GL, or may be part of the gate line GL.

Referring to FIGS. 15 and 16, a first capacitor electrode CE1 of the storage capacitor Cst is formed on the gate insulating film 140. The first capacitor electrode CE1 may be formed by the same process by the same material as the gate electrodes G1, G2.

An interlayer insulating film 180 is disposed on the gate electrodes G1, G2 and the first capacitor electrode CE1.

The data line DL and the drive power line PL are disposed on the interlayer insulating film 180. Further, the source electrode S1 and the drain electrode D1 of the first thin film transistor TR1 are disposed on the interlayer insulating film 180, and the source electrode S2 and the drain electrode D2 of the second thin film transistor TR2 are disposed on the interlayer insulating film 180.

The source electrode S1 of the first thin film transistor TR1 may be formed integrally with the data line DL, and may have a structure extending from the data line DL.

The source electrode S1 of the first thin film transistor TR1 may be in contact with a side of the active layer A1 of the first thin film transistor TR1 through the first contact hole H1.

The drain electrode D1 of the first thin film transistor TR1 is in contact with the other side of the active layer A1 of the first thin film transistor TR1 through the second contact hole H2. Further, the drain electrode D1 of the first thin film transistor TR1 is connected to the first capacitor electrode CE1 through the third contact hole H3. As a result, the first capacitor electrode CE1 can be connected with the first thin film transistor TR1.

The drain electrode D2 of the second thin film transistor TR1 may be formed integrally with the drive power line PL, and may have a structure extending from the drive power line PL.

The drain electrode D2 of the second thin film transistor TR1 may be in contact with a side of the active layer A2 of the second thin film transistor TR2 through the sixth contact hole H6.

The source electrode S2 of the second thin-film transistor TR2 is in contact with another side of the active layer A2 of the second thin-film transistor TR2 through the fifth contact hole H5. Further, the source electrode S2 of the second thin-film transistor TR2 is connected to the light shielding layer 111 through the fourth contact hole H4. A voltage equal to the source electrode S2 of the second thin-film transistor TR2 may be applied to the light shielding layer 111 overlapping the second thin-film transistor TR2.

The source electrode S2 of the second thin film transistor TR2 may extend over the interlayer insulating layer 180 to form the second capacitor electrode CE2 of the storage capacitor Cst.

According to one embodiment of the present invention, the first capacitor electrode CE1 and the second capacitor electrode CE2 may be overlapped to form the storage capacitor Cst.

Referring to FIGS. 14 and 15, a planarization layer 190 is disposed on the data line DL, the drive power line PL, the source electrodes S1, S2, the drain electrodes D1, D2, and the second capacitor electrode CE2. The planarization layer 190 planarizes the top of the first thin-film transistor TR1 and the second thin-film transistor TR2, and protects the first thin-film transistor TR1 and the second thin-film transistor TR2. The planarization layer 190 acts as a protective layer.

On the planarization layer 190, the first electrode 711 of the display element 710 is disposed. The first electrode 711 of the display element 710 is in contact with the second capacitor electrode CE2 through the seventh contact hole H7 formed in the planarization layer 190. As a result, the first electrode 711 of the display element 710 can be connected with the source electrode S2 of the second thin film transistor TR2.

A bank layer 750 is disposed on the edge of the first electrode 711. The bank layer 750 defines the light emitting region of the display element 710.

An organic light-emitting layer 712 is disposed on the first electrode 711, and a second electrode 713 is disposed on the organic light-emitting layer 712. Accordingly, the display element 710 is completed. The display element 710 shown in FIG. 15 is an organic light-emitting diode (OLED). Thus, the display apparatus 1000 according to one embodiment of the present invention is an organic light-emitting display device.

The pixel drive circuit (PDC) according to another embodiment of the present invention may be formed in a variety of structures other than those described above. The pixel drive circuit (PDC) may include, for example, three or more thin film transistors.

According to the present disclosure, the following advantageous effects may be obtained.

The thin film transistor according to one embodiment of the present invention can prevent or suppress the threshold voltage Vth from being shifted in the negative direction by including a depletion control layer disposed on the active layer, even if the channel of the active layer has a short channel.

The thin film transistor according to one embodiment of the present invention can control the depth of conductorization penetration by including a depletion control layer disposed on the active layer, even if the channel of the active layer has a short channel.

The thin film transistor according to one embodiment of the present invention can have excellent reliability by including a depletion control layer disposed on the active layer.

It will be apparent to those skilled in the art that various modifications and variations can be made in the thin film transistor and the display apparatus comprising the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A thin film transistor, comprising:
an active layer;
a depletion control layer on the active layer; and
a gate electrode spaced apart from the active layer and overlapping at least partially with the active layer;
wherein the active layer comprises:
a channel portion overlapping at least partially with the gate electrode;
a first connecting portion connected to one side of the channel portion; and
a second connecting portion connected to the other side of the channel portion;
wherein the depletion control layer overlaps at least a portion of the gate electrode in a plane,
the depletion control layer includes a first material,
wherein the active layer includes a second material, and
wherein the first material has a larger work function than the second material.

2. The thin film transistor of claim 1, wherein a difference between the work function of the first material and the work function of the second material is 0.3 eV or more.

3. The thin film transistor of claim 1, wherein the depletion control layer is in contact with the active layer, forming a Schottky barrier with the active layer, and
wherein the active layer comprises a depletion region overlapping the depletion control layer.

4. The thin film transistor of claim 1, wherein a region of the channel portion that overlaps with the depletion control layer has a greater resistivity than a region of the channel portion that does not overlap with the depletion control layer.

5. The thin film transistor of claim 1, wherein the first material comprises a metal or an oxide semiconductor material,
wherein the metal comprises at least one of gallium (Ga), zinc (Zn), tin (Sn), and titanium (Ti), and
wherein the oxide semiconductor material comprises at least one of IGZO (InGaZnO), GZO (GaZnO), IGO (InGaO), IZO (InZnO), GZTO (GaZnSnO), IGZTO (InGaZnSnO), ITO (InSnO), ITZO (InSnZnO)-based oxide semiconductor material,
wherein the second material comprises at least one of IZO (InZnO), IGO (InGaO), ITO (InSnO), IGZO (InGaZnO), IGZTO (InGaZnSnO), GZTO (GaZnSnO), GZO (GaZnO), ITZO (InSnZnO) and FIZO (FeInZnO)-based oxide semiconductor materials.

6. The thin film transistor of claim 1, wherein the depletion control layer comprises a first depletion control layer overlapping at least a portion of the first connecting portion.

7. The thin film transistor of claim 6, wherein a region of the first connecting portion that overlaps the first depletion control layer has a greater resistivity than a region of the first connecting portion that does not overlap the depletion control layer.

8. The thin film transistor of claim 6, wherein the first depletion control layer includes a first sub-depletion control layer and a second sub-depletion control layer,
wherein the first sub-depletion control layer and the second sub-depletion control layer are spaced apart from each other.

9. The thin film transistor of claim 1, wherein the depletion control layer comprises a second depletion control layer overlapping at least a portion of the second connecting portion.

10. The thin film transistor of claim 9, wherein a region of the second connecting portion that overlaps with the second depletion control layer has a greater resistivity than a region of the second connecting portion that does not overlap with the depletion control layer.

11. The thin film transistor of claim 9, wherein the second depletion control layer includes a first sub-depletion control layer and a second sub-depletion control layer,
the first sub-depletion control layer and the second sub-depletion control layer are spaced apart from each other.

12. The thin film transistor of claim 1, wherein the depletion control layer includes a first depletion control layer overlapping at least a portion of the first connecting portion and a second depletion control layer overlapping at least a portion of the second connecting portion, and
wherein the first depletion control layer and the second depletion control layer spaced apart from each other.

13. The thin film transistor of claim 12, wherein the first depletion control layer and the second depletion control layer each comprises a first sub-depletion control layer and a second sub-depletion control layer, and
wherein the first sub-depletion control layer and the second sub-depletion control layer are spaced apart from each other.

14. The thin film transistor of claim 12, when a direction parallel to a straight line connecting the first connecting portion and the second connecting portion for the shortest distance is referred to as a first direction, any straight line parallel to the first direction and passing through a portion of the first depletion control layer does not pass through the second depletion control layer.

15. The thin film transistor of claim 12, when the direction parallel to the straight line connecting the first connecting portion and the second connecting portion for the shortest distance is referred to as the first direction, any straight line parallel to the first direction and passing through a portion of the first depletion layer passes through the second depletion layer.

16. The thin film transistor of claim 13, wherein a size of the region where the first sub-depletion control layer of the first depletion control layer overlaps the gate electrode is different from the size of the region where the second sub-depletion control layer of the first depletion control layer overlaps the gate electrode, and
wherein a size of the region where the first sub-depletion control layer of the second depletion control layer overlaps the gate electrode is different from the size of the region where the second sub-depletion control layer of the second depletion control layer overlaps the gate electrode.

17. The thin film transistor of claim 11, wherein the depletion control layer comprises a third depletion control layer that does not overlap the first connecting portion and the second connecting portion.

18. A display apparatus comprising the thin film transistor of claim 1.
